(19) United States
(12) Patent Application Publication
(10) Pub. No.: US 2026/0314184 A1
(43) Pub. Date: Oct. 8, 2026

(54) DISPLAY PANEL AND ELECTRONIC DEVICE INCLUDING THE SAME

(71) Applicant: Samsung Display Co., Ltd., Yongin-si (KR)

(72) Inventors: Namjin KIM, Yongin-si (KR); Yeonju SEO, Yongin-si (KR); Wonjang KI, Yongin-si (KR); Daehyun NOH, Yongin-si (KR); Seongsik AHN, Yongin-si (KR); Hyungchul LIM, Yongin-si (KR)

(73) Assignee: Samsung Display Co., Ltd., Yongin-si (KR)

(21) Appl. No.: 19/462,530

(22) Filed: Jan. 28, 2026

(30) Foreign Application Priority Data
Apr. 4, 2025 (KR) 10-2025-0044272

(51) Int. Cl. H10K 59/122; H10K 59/80

(52) U.S. Cl. CPC H10K 59/122; H10K 59/873

(57) ABSTRACT

Provided is a display panel including a substrate including a display area, a bending area at one side of the display area, a first area between the display area and the bending area, and a second area on the bending area opposite to the first area, a light-emitting diode in the display area, a first dam part and a second dam part in the first area, a bank part extending across the bending area, and a third dam part and a fourth dam part in the second area, wherein at least one of a the following three conditions is satisfied: a width of the second dam part is less than or equal to 51 micrometers, a distance between the second dam part and the bank part is greater than or equal to 30 micrometers, and a distance between the third dam part and the fourth dam part is greater than or equal to 28 micrometers in a direction from the first area to the second area.

### CROSS-REFERENCE TO RELATED APPLICATION

This application claims priority to Korean Patent Application No. 10-2025-0044272, filed on Apr. 4, 2025, in the Korean Intellectual Property Office, the disclosure of which is incorporated by reference herein in its entirety.

### BACKGROUND

### 1. Field

One or more embodiments of the present disclosure relate to a display panel that may include a light-emitting diode and an electronic device including the same.

### 2. Description of Related Art

Electronic devices may display video and/or images by using a display panel included therein. Recently, display panels have been used in a greater variety of ways, and various functions that are incorporated into or linked to display panels have been proposed. A display panel may be configured to be bent in some areas so that a portion of the display panel may be arranged under another portion of the display panel.

Cracks may occur in a bending area of a display panel. The cracks may degrade functions of the display panel or cause errors, thereby degrading quality of the display panel. A method or structure whereby cracks that occur in the bending area of the display panel may be reduced is required.

### SUMMARY

One or more embodiments provide a display panel including a light-emitting diode and an electronic device including the same.

Additional aspects will be set forth in part in the description which follows and, in part, will be apparent from the description, or may be learned by practice of one or more embodiments.

According to an aspect of one or more embodiments, there is provided a display panel including a substrate including a display area, a bending area at one side of the display area, a first area between the display area and the bending area, and a second area where the bending area is between the first area and the second area, a light-emitting diode in the display area, a first dam part and a second dam part in the first area, a bank part extending across the bending area, and a third dam part and a fourth dam part in the second area, wherein at least one of the following three conditions is satisfied: a width of the second dam part is less than or equal to 51 micrometers, a distance between the second dam part and the bank part is greater than or equal to 30 micrometers, and a distance between the third dam part and the fourth dam part is greater than or equal to 28 micrometers in a direction from the first area to the second area.

The width of the second dam part may be greater than or equal to 10 micrometers and less than or equal to 50 micrometers.

The distance between the second dam part and the bank part may be greater than or equal to 50 micrometers.

The distance between the third dam part and the fourth dam part may be greater than or equal to 30 micrometers and less than or equal to 120 micrometers.

An angle between a side surface of the second dam part and a lower surface of the second dam part may be less than or equal to 60 degrees.

An angle between a side surface of the bank part and a lower surface of the bank part may be less than or equal to 60 degrees.

An angle between a side surface of the third dam part and a lower surface of the third dam part or an angle between a side surface of the fourth dam part and a lower surface of the fourth dam part may be less than or equal to 60 degrees.

The display panel may further include a first inorganic encapsulation layer at least partially on the first dam part, the second dam part, and the bank part, and a second inorganic encapsulation layer on the first inorganic encapsulation layer, wherein the first inorganic encapsulation layer and the second inorganic encapsulation layer are in direct contact with each other between the second dam part and the bank part.

The display panel may further include an inorganic insulating layer below the first dam part, the second dam part, the bank part, the third dam part, and the fourth dam part, wherein the first inorganic encapsulation layer and the inorganic insulating layer are in direct contact with each other between the second dam part and the bank part.

The inorganic insulating layer may include an opening corresponding to the bending area.

The display panel may further include a conductive layer below the first dam part, wherein the conductive layer may overlap the first dam part and the second dam part.

The conductive layer may overlap the bank part.

The display panel may further include a touch sensing layer on the light-emitting diode, the touch sensing layer including a touch insulating layer and a touch conductive layer, wherein a portion of the touch insulating layer may extend to the first area and includes a groove between the second dam part and the bank part.

The display panel may further include a planarization layer on the first dam part, the second dam part, the bank part, the third dam part, and the fourth dam part.

The bank part and the substrate may be in direct contact with each other in the bending area.

A portion of the substrate that corresponds to the bending area may be bent, and a second portion of the substrate that corresponds to the second area may be below a bottom surface of a first portion of the substrate that corresponds to the first area.

The first dam part, the second dam part, the bank part, the third dam part, and the fourth dam part may include an organic insulating material.

The first area may be in a first direction with respect to the display area, the bending area may be in the first direction with respect to the first area, the second area may be in the first direction with respect to the bending area, the second dam part may be in the first direction with respect to the first dam part, the bank part may be in the first direction with respect to the second dam part, the third dam part may be in the first direction with respect to the bank part, and the fourth dam part may be in the first direction with respect to the third dam part.

According to another aspect of one or more embodiments, there is provided a display panel including a substrate including a display area, a bending area in a first direction with respect to the display area, a first area between the display area and the bending area, and a second area in the first direction with respect to the bending area opposite to the first area, a light-emitting diode in the display area, a first dam part in the first area, a second dam part in the first direction with respect to the first dam part, the second dam part having a first length in the first direction, a bank part spaced apart from the second dam part by a second length in the first direction and extending across the bending area, and a third dam part and a fourth dam part in the second area and spaced apart from each other by a third length in the first direction, wherein at least one of the following three conditions is satisfied: the first length is less than or equal to 51 micrometers, the second length is greater than or equal to 30 micrometers, and the third length is greater than or equal to 28 micrometers.

According to still another aspect of one or more embodiments, there is provided an electronic device including a display panel, and a processor configured to drive the display panel, wherein the display panel includes a substrate including a display area, a bending area at one side of the display area, a first area between the display area and the bending area, and a second area where the bending area is between the first area and the second area, a light-emitting diode in the display area, a first dam part and a second dam part in the first area, a bank part extending across the bending area, and a third dam part and a fourth dam part in the second area, wherein at least one of the following three conditions is satisfied: a width of the second dam part is less than or equal to 51 micrometers, a distance between the second dam part and the bank part is greater than or equal to 30 micrometers, and a distance between the third dam part and the fourth dam part is greater than or equal to 28 micrometers in a direction from the first area to the second area.

### BRIEF DESCRIPTION OF DRAWINGS

The above and other aspects, features, and advantages of embodiments will be more apparent from the following description taken in conjunction with the accompanying drawings, in which:

FIG. 1 is a block diagram of an electronic device according to one or more embodiments;

FIGS. 2, 3, and 4 are schematic diagrams of an electronic device according to one or more embodiments;

FIG. 5 is a plan view of a display panel according to one or more embodiments;

FIG. 6 is a cross-sectional view of a display panel according to one or more embodiments;

FIG. 7 is an equivalent circuit diagram of a light-emitting diode and a pixel circuit connected thereto, which are included in one pixel of a display panel according to one or more embodiments;

FIG. 8 is a cross-sectional view of a display panel according to one or more embodiments;

FIG. 9 is a cross-sectional view of a display panel according to one or more embodiments;

FIG. 10 is an enlarged cross-sectional view of a display panel according to one or more embodiments;

FIG. 11 is an enlarged cross-sectional view of a display panel according to one or more embodiments;

FIG. 12 is a cross-sectional view of a display panel according to one or more embodiments; and

FIG. 13 is a cross-sectional view of a display panel according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expressions “at least one of a, b or c” and “at least one of a, b and c” each indicate only a, only b, only c, both a and b, both a and c, both b and c, all of a, b, and c, or variations thereof.

As the present description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. The present embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of description, the following embodiments are not limited thereto.

When one or more embodiments may be implemented differently, a certain process order may be performed differently from the described order. For example, two consecutively described processes may be performed substantially at the same time or performed in an order opposite to the described order.

As used herein, the expression “A and/or B” refers to A, B, or A and B.

It will be further understood that, when layers, regions, or elements are referred to as being (e.g., electrically) connected to each other, they may be directly (e.g., electrically) connected to each other and/or may be indirectly (e.g., electrically) connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may not be perpendicular to one another.

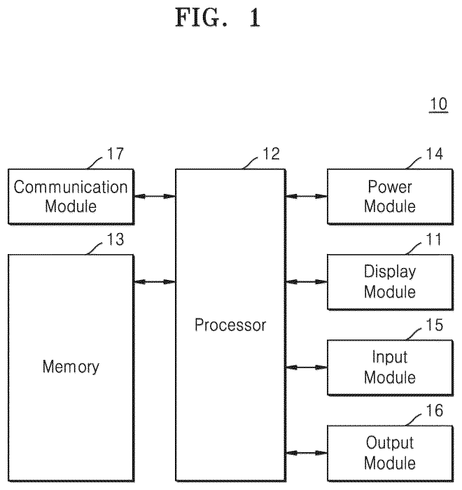

FIG. 1 is a block diagram of an electronic device 10 according to one or more embodiments. Referring to FIG. 1, the electronic device 10 may include a display panel 11, a processor 12, a memory 13, and a power module 14.

The processor 12 may include, for example, at least one of a central processing unit (CPU), an application processor (AP), a graphics processing unit (GPU), a communication processor (CP), an image signal processor (ISP), and a controller. In one or more embodiments, the processor 12 may be split into two or more from a functional or structural perspective. For example, the processor 12 may include a main processor in the form of a first drive chip including a CPU, and an auxiliary processor in the form of a second drive chip including a controller configured to receive an image signal from the main processor and process the image signal to meet interface specifications of the display panel 11.

The memory 13 may include at least one of a non-volatile memory and a volatile memory. Data information required for an operation of the processor 12 or the display panel 11 may be stored in the memory 13. When the processor 12 executes an application stored in the memory 13, an image data signal and/or an input control signal may be transmitted to the display panel 11, and the display panel 11 may process the received signal and output image information through a display screen.

The power module 14 which may include a power supply, such as a power adapter or a battery device, and a power converter configured to convert power supplied by the power supply and generate power required for an operation of the electronic device 10. Power conversion by the power converter may include, but is not limited to, at least one of a DC-DC converter, an AC-DC converter, and a DC-AC converter.

The electronic device 10 may further include an input module 15, a non-image output module 16 and/or a communication module 17 which may be referred to as an input interface, a non-image output interface, and a communication interface, respectively.

The input module 15 may provide input information to the processor 12 and/or the display panel 11. The input module 15 may include not only a physical button, a keyboard, and a microphone but also various sensor modules. Examples of the sensor modules may include not only a touch sensor, a pressure sensor, a distance sensor, a position sensor, a digitizer, a motion recognition sensor, a camera sensor, a light receiving sensor, a photoelectric conversion sensor, and a temperature sensor but also biometric sensors such as a blood pressure sensor, a blood sugar sensor, an electrocardiogram sensor, and a heart rate sensor.

The non-image output module 16 may receive information other than an image received from the processor 12 and provide the information to a user. Examples of the non-image output module 16 may include an audio module, a haptic module, a light-emitting module, etc., and may include another functional module unique to an electronic device (e.g., a cooling module of a refrigerator, etc.).

The communication module 17 is a module for transmission and reception of information between the electronic device 10 and an external device and may include a receiver and a transmitter. The communication module 17 may include various wireless communication modules such as a mobile communication module, a Wi-Fi module, and a Bluetooth module, or various wired communication modules.

At least one of the above elements of the electronic device 10 may be included in a display apparatus. In one or more embodiments, some of the individual modules functionally included in one module may be included in the display apparatus, and the others may be provided separately from the display apparatus. For example, the display apparatus may include the display panel 11, and the processor 12, the memory 13, and the power module 14 may be provided in the form of an apparatus in the electronic device 10 other than the display apparatus. As another example, the power module 14 may be prepared in the display apparatus and may supply power to the processor 12 and the memory 13 provided in the electronic device 10 other than the display apparatus, but embodiments are not limited to the above examples.

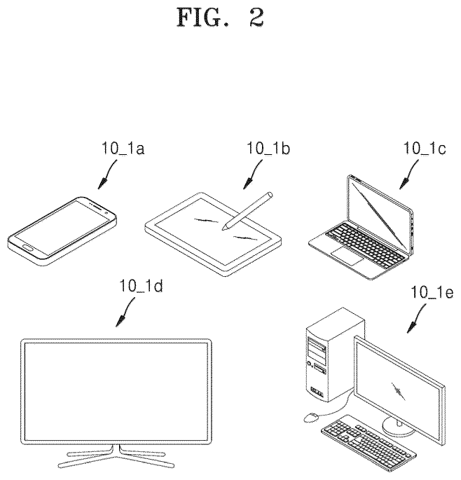

FIGS. 2 to 4 are schematic diagrams of an electronic device according to one or more embodiments. FIGS. 2 to 4 show examples of various electronic devices to which a display apparatus according to one or more embodiments is applied.

FIG. 2 shows a smartphone 10_1a, a tablet personal computer (PC) 10_1b, a laptop 10_1c, a television (TV) 10_1d, and a desk monitor 10_1e as examples of an electronic device.

The smartphone 10_1a may include an input module such as a touch sensor and a communication module in addition to a display panel. The smartphone 10_1a may process information received through the communication module or other input modules and display the information through the display panel of the display apparatus.

In a similar way to the smartphone 10_1a, the tablet PC 10_1b, the laptop 10_1c, the TV 10_1d, and the desk monitor 10_1e may also include a display panel and an input module, and in some cases, may further include a communication module.

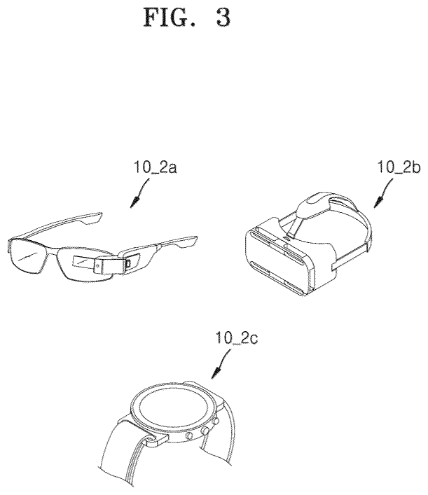

FIG. 3 shows an embodiment where an electronic device including a display panel is applied to a wearable electronic device. The wearable electronic device may be smartglasses 10_2a, a head mounted display 10_2b, a smartwatch 10_2c, etc.

The smartglasses 10_2a and the head mounted display 10_2b may include a display panel that projects a display image and a reflector that reflects the projected display image and provides the same to the user's eyes and thus may provide a virtual reality or augmented reality screen to the user.

The smartwatch 10_2c may include a biometric sensor as an input device and may provide biometric information recognized through the biometric sensor to the user through the display panel.

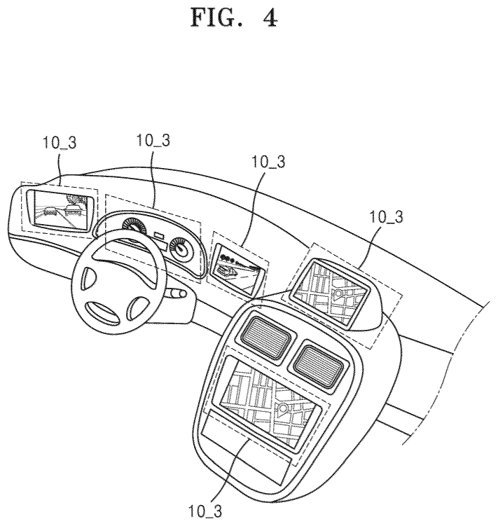

FIG. 4 shows an embodiment where an electronic device including a display panel is applied to a vehicle. For example, an electronic device 10_3 may be applied to an instrument panel, center fascia, etc., of a car or may be applied to a center information display (CID) arranged on a dashboard of a car or a room mirror display replacing a side mirror.

An electronic device to which a display apparatus according to one or more embodiments is applied may include not only devices that mainly display the screen, such as a billboard, an electronic board, and a game console, but also various home appliances that display information through the display panel, such as a refrigerator, a washing machine, a dryer, an air conditioner, and a robot vacuum cleaner. In addition, when a display panel has the function of transmitting light, the display panel may be applied to an electronic device such as a smart window or a transparent display apparatus that displays a background and a display image together. Types of electronic devices according to embodiments are not limited to the above examples, and application of various other electronic devices not described as examples may also be possible.

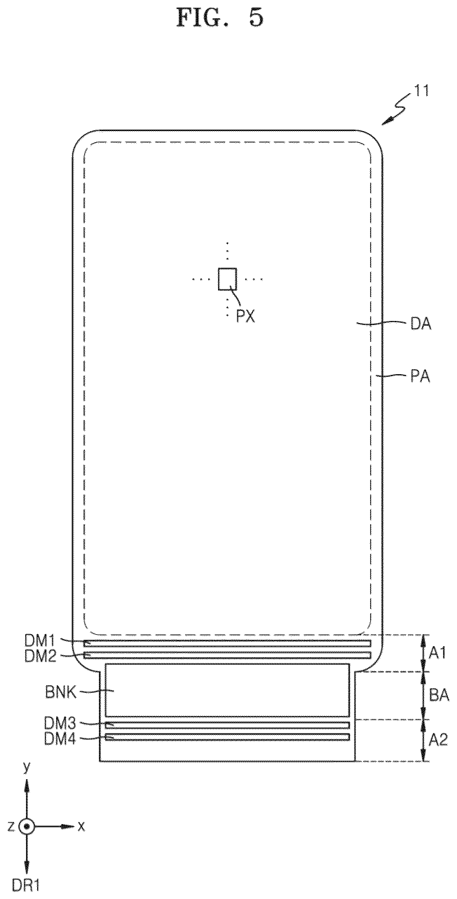

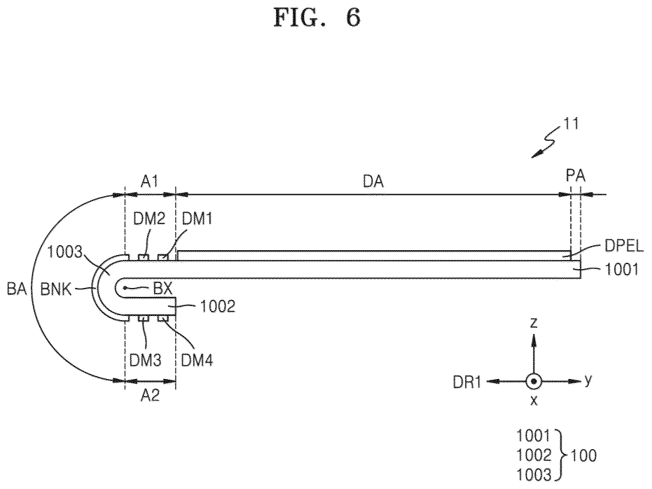

FIG. 5 is a plan view of the display panel 11 according to one or more embodiments. FIG. 6 is a cross-sectional view of the display panel 11 according to one or more embodiments.

Referring to FIGS. 5 and 6, the display panel 11 applied to the smartphone 10_1a (refer to FIG. 2) among the electronic devices 10 described above is shown. However, embodiments are not limited thereto. In one or more embodiments, the display panel 11 may have an overall quadrangular (e.g., rectangular) shape with round corners. FIG. 5 shows one or more embodiments in which the display panel 11 has short sides extending in the x-axis direction and long sides extending in the y-axis direction. In another embodiment, the display panel 11 may have short sides extending in the y-axis direction and long sides extending in the x-axis direction. In one or more embodiments, the display panel 11 does not necessarily have a rectangular shape in a plan view and may have any shape such as another polygonal shape, a circular shape, an oval shape, an irregular shape, etc.

The display panel 11 may include a display area DA, a peripheral area PA, a first area A1, a second area A2, and a bending area BA. In one or more embodiments, the display panel 11 may include a substrate 100, and the substrate 100 may include the display area DA, the peripheral area PA, the first area A1, the second area A2, and the bending area BA. In one or more embodiments, it may be understood that the display area DA, the peripheral area PA, the first area A1, the second area A2, and the bending area BA are defined on the display panel 11 and/or the substrate 100.

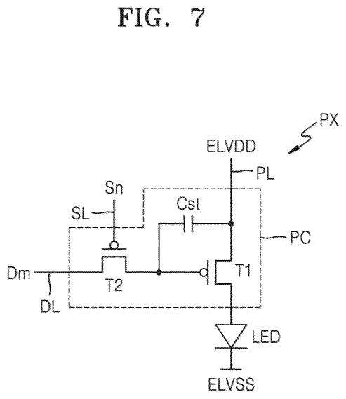

The display area DA may be an area where a display element of the display panel 11 is arranged. A plurality of pixels PX may be arranged in the display area DA. Each pixel PX may emit light of a certain color through a corresponding light-emitting diode LED (refer to FIG. 7) and a pixel circuit PC (refer to FIG. 7). The display panel 11 may display an image through light emitted from each pixel PX.

The peripheral area PA may be arranged adjacent to and/or around the display area DA. The peripheral area PA may at least partially (e.g., entirely) surround the display area DA. The peripheral area PA may be an area displaying no image, that is, a non-display area. Lines for driving the pixel PX of the display area DA, for example, a signal line, a voltage line, etc., may be arranged in the peripheral area PA. FIG. 5 shows the peripheral area PA, the first area A1, the second area A2, and the bending area BA individually. However, in one or more embodiments, the first area A1, the second area A2, and the bending area BA may be classified as a portion of the peripheral area PA.

The first area A1 may be arranged at one side of the display area DA. In one or more embodiments, the first area A1 may be arranged in a first direction DR1 with respect to the display area DA. In one or more embodiments, the first direction DR1 may be opposite to the y-axis direction. In one or more embodiments, the first area A1 may include corners of the display panel 11 or the substrate 100. In one or more embodiments, the display panel 11 may have an x-direction length that changes in the first area A1. Accordingly, an x-direction length of the display panel 11 in the bending area BA and the second area A2 may be less than an x-direction length of the display panel 11 in the first area A1. Such a difference in the x-direction length of the display panel 11 may allow easy bending in the bending area BA described below.

The bending area BA may be arranged at one side of the first area A1 opposite to the display area DA. In one or more embodiments, the bending area BA may be arranged in the first direction DR1 with respect to the first area A1. In one or more embodiments, the first area A1 may be arranged between the bending area BA and the display area DA. In one or more embodiments, the bending area BA may be an area where the display panel 11 and the substrate 100 may be bent. In one or more embodiments, some of the layers of the display panel 11 may be removed (that is, may not be included) in the bending area BA to allow easier bending in the bending area BA.

The second area A2 may be arranged at one side of the bending area BA opposite to the first area A1. In one or more embodiments, the second area A2 may be arranged in the first direction DR1 with respect to the bending area BA. In one or more embodiments, the second area A2 may be arranged opposite to the first area A1 with the bending area BA therebetween. In one or more embodiments, the second area A2 may be arranged in the first direction DR1 with respect to the first area A1 with the bending area BA therebetween.

A display element layer DPEL may be arranged on the substrate 100 in the display area DA. A detailed structure of the display element layer DPEL is described below.

A first dam part DM1 and a second dam part DM2 may be arranged on the substrate 100 in the first area A1. In one or more embodiments, the first dam part DM1 and the second dam part DM2 may extend in a direction, for example, the x-axis direction, perpendicular to a direction (e.g., the first direction DR1) in which the first area A1, the bending area BA, and the second area A2 are arranged. In one or more embodiments, the second dam part DM2 may be arranged in the first direction DR1 with respect to the first dam part DM1.

A third dam part DM3 and a fourth dam part DM4 may be arranged on the substrate 100 in the second area A2. In one or more embodiments, the third dam part DM3 and the fourth dam part DM4 may extend in a direction, for example, the x-axis direction, perpendicular to a direction (e.g., the first direction DR1) in which the first area A1, the bending area BA, and the second area A2 are arranged. In one or more embodiments, the fourth dam part DM4 may be arranged in the first direction DR1 with respect to the third dam part DM3.

A bank part BNK may be arranged in the first area A1, the bending area BA, and the second area A2. In one or more embodiments, one end, for example, a y-axis direction end, of the bank part BNK may be arranged in the first area A1. In one or more embodiments, the other end, for example, a first direction DR1 end, of the bank part BNK may be arranged in the second area A2. In one or more embodiments, the bank part BNK may extend to at least partially or entirely cover and/or be arranged on the bending area BA. In one or more embodiments, the bank part BNK may be arranged between the second dam part DM2 and the third dam part DM3.

The display panel 11 according to one or more embodiments may be bent in a certain area. In one or more embodiments, the display panel 11 may be bent in the bending area BA. In one or more embodiments, the display panel 11 may be bent around a bending axis BAX in the bending area BA. FIG. 5 shows one or more embodiments in which the display panel 11 is not bent, and FIG. 6 shows one or more embodiments in which the display panel 11 is bent. In one or more embodiments, the display panel 11 may include the substrate 100, and thus, the substrate 100 may be bent in the bending area BA. The substrate 100 may include a first portion 1001, a second portion 1002, and a third portion 1003. The third portion 1003 may be arranged between the first portion 1001 and the second portion 1002. The third portion 1003 of the substrate 100 may be a portion that may be bent. As bending occurs in the third portion 1003 of the substrate 100, the second portion 1002 may be arranged under a bottom surface of the first portion 1001, for example, opposite to the z-axis direction. In one or more embodiments, the first dam part DM1 and the second dam part DM2 may be arranged on the first portion 1001 of the substrate 100, and the third dam part DM3 and the fourth dam part DM4 may be arranged on the second portion 1002 of the substrate 100. As the substrate 100 is bent, the third dam part DM3 and the fourth dam part DM4 may be arranged under the first portion 1001 of the substrate 100, for example, under the first dam part DM1 and the second dam part DM2. In one or more embodiments, one end of the bank part BNK of the substrate 100 may be arranged on the first portion 1001 of the substrate 100, the other end of the bank part BNK may be arranged on the second portion 1002 of the substrate 100, and the bank part BNK may extend over the third portion 1003 of the substrate 100. As the third portion 1003 of the substrate 100 is bent, the bank part BNK may also be bent.

FIG. 7 is an equivalent circuit diagram of the light-emitting diode LED and the pixel circuit PC connected thereto, which are included in one pixel PX of a display panel according to one or more embodiments.

Referring to FIG. 7, the pixel circuit PC may be connected to the light-emitting diode LED to implement light emission of the pixels PX. In one or more embodiments, the light-emitting diode LED may be an organic light-emitting diode. The pixel circuit PC may include a first transistor T1, a second transistor T2, and a storage capacitor Cst. In one or more embodiments, the first transistor T1 may be a driving transistor, and the second transistor T2 may be a switching transistor. The second transistor T2 may be connected to a scan line SL and a data line DL and may be configured to transmit a data signal Dm input through the data line DL to the first transistor T1 according to a scan signal Sn input through the scan line SL.

The storage capacitor Cst may be connected to the second transistor T2 and a driving voltage line PL and may store a voltage corresponding to a difference between a voltage received from the second transistor T2 and a driving voltage ELVDD supplied to the driving voltage line PL.

The first transistor T1 may be connected to the driving voltage line PL and the storage capacitor Cst and may be configured to control a driving current flowing through the light-emitting diode LED from the driving voltage line PL to correspond to a voltage value stored in the storage capacitor Cst. The light-emitting diode LED may emit light having a certain luminance according to the driving current.

The pixel circuit PC is not limited to the numbers of thin-film transistors and storage capacitors and the circuit design described with reference to FIG. 7, and the numbers thereof and the circuit design may be variously modified.

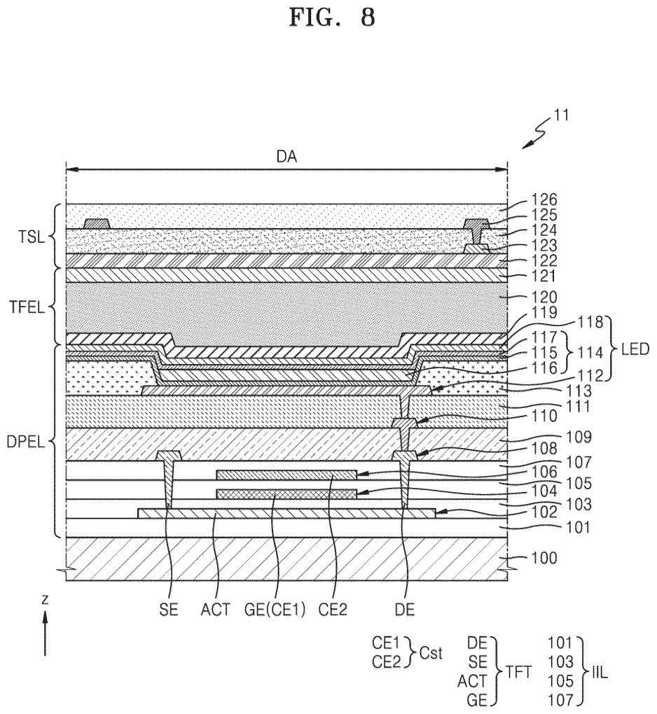

FIG. 8 is a cross-sectional view of the display panel 11 according to one or more embodiments. FIG. 8 may be a cross-sectional view of the display panel 11 in the display area DA.

Referring to FIG. 8, the display element layer DPEL, a thin-film encapsulation layer TFEL, and a touch sensing layer TSL may be sequentially arranged on the substrate 100.

The display element layer DPEL may include the light-emitting diode LED and a thin-film transistor TFT connected to the light-emitting diode LED. In one or more embodiments, FIG. 8 may schematically show a portion of the pixel circuit PC described with reference to FIG. 7. For example, the thin-film transistor TFT connected to the light-emitting diode LED may correspond to a transistor connected to the light-emitting diode LED, for example, the first transistor T1, among the transistors shown in FIG. 7.

The substrate 100 may include a glass material or polymer resin. In one or more embodiments, the substrate 100 may include a stacked structure of a base layer including polymer resin and a barrier layer including an inorganic insulating material. The polymer resin may include at least one of materials such as polyethersulfone, polyarylate, polyetherimide, polyethylene naphthalate, polyethylene terephthalate, polyphenylene sulfide, polyimide, polycarbonate, cellulose triacetate, and cellulose acetate propionate. The inorganic insulating material may include at least one of materials such as silicon oxide (SiO₂) and silicon nitride (SiNₓ). However, embodiments are not limited thereto.

The thin-film transistor TFT and an inorganic insulating layer IIL may be arranged on the substrate 100. The inorganic insulating layer IIL may include a plurality of layers, and each element of the thin-film transistor TFT may be arranged between each layer of the inorganic insulating layer IIL. The thin-film transistor TFT may include an active pattern ACT, a gate electrode GE, a source electrode SE, and a drain electrode DE. The inorganic insulating layer IIL may include a first insulating layer 101, a second insulating layer 103, a third insulating layer 105, and a fourth insulating layer 107.

The first insulating layer 101 may be arranged on the substrate 100. The first insulating layer 101 may entirely cover and/or be arranged on the substrate 100. The first insulating layer 101 may have a flat upper surface. The first insulating layer 101 may include an inorganic insulating material. In one or more embodiments, the first insulating layer 101 may include at least one of materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer or multi-layer structure. In one or more embodiments, the first insulating layer 101 may be a buffer layer. A conductive layer overlapping the thin-film transistor TFT may be arranged between the first insulating layer 101 and the substrate 100.

A semiconductor layer 102 may be arranged on the first insulating layer 101. The semiconductor layer 102 may include the active pattern ACT. The active pattern ACT may include a source region overlapping the source electrode SE, a drain region overlapping the drain electrode DE, and a channel region between the source region and the drain region. The channel region may overlap the gate electrode GE. The source region and the drain region may be regions doped with impurities (e.g., dopants).

The second insulating layer 103 may be arranged over and/or on the semiconductor layer 102. The second insulating layer 103 may cover and/or be arranged on the semiconductor layer 102, for example, the active pattern ACT. The second insulating layer 103 may include an inorganic insulating material. In one or more embodiments, the second insulating layer 103 may include at least one of materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer or multi-layer structure. In one or more embodiments, the second insulating layer 103 may be a first gate insulating layer.

The storage capacitor Cst may be arranged on the second insulating layer 103. The storage capacitor Cst may include a first capacitor electrode CE1 and a second capacitor electrode CE2. The first capacitor electrode CE1 and the second capacitor electrode CE2 may overlap each other in the z-axis direction, and the second capacitor electrode CE2 may be arranged above the first capacitor electrode CE1 in the z-axis direction.

A second conductive layer 104 may be arranged on the second insulating layer 103. The second conductive layer 104 may include the gate electrode GE of the thin-film transistor TFT and the first capacitor electrode CE1 of the storage capacitor Cst. In one or more embodiments, the gate electrode GE and the first capacitor electrode CE1 may be integrally formed with each other as shown in FIG. 8. In one or more embodiments, the gate electrode GE and the first capacitor electrode CE1 may be provided individually. In one or more embodiments, the second conductive layer 104 may include at least one of materials such as, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) and may have a single-layer or multi-layer structure.

The third insulating layer 105 may be arranged over and/or on the second conductive layer 104. The third insulating layer 105 may cover and/or be arranged on the second conductive layer 104, for example, the gate electrode GE and the first capacitor electrode CE1. The third insulating layer 105 may include an inorganic insulating material. In one or more embodiments, the third insulating layer 105 may include at least one of materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer or multi-layer structure. In one or more embodiments, the third insulating layer 105 may be a second gate insulating layer.

A third conductive layer 106 may be arranged on the third insulating layer 105. The third conductive layer 106 may include the second capacitor electrode CE2. The second capacitor electrode CE2 may overlap the first capacitor electrode CE1 in the z-axis direction. In one or more embodiments, the third conductive layer 106 may include at least one of materials such as, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) and may have a single-layer or multi-layer structure.

The fourth insulating layer 107 may be arranged over and/or on the third conductive layer 106. The fourth insulating layer 107 may cover and/or be arranged on the third conductive layer 106, for example, the second capacitor electrode CE2. The fourth insulating layer 107 may include an inorganic insulating material. In one or more embodiments, the fourth insulating layer 107 may include at least one of materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer or multi-layer structure. In one or more embodiments, the fourth insulating layer 107 may be an interlayer insulating layer.

A fourth conductive layer 108 may be arranged on the fourth insulating layer 107. The fourth conductive layer 108 may include the source electrode SE and the drain electrode DE. The source electrode SE may overlap the source region of the active pattern ACT in the z-axis direction. The source electrode SE may be connected to the active pattern ACT (e.g., the source region) through an opening defined in the second to fourth insulating layers 103, 105, and 107. The drain electrode DE may overlap the drain region of the active pattern ACT in the z-axis direction. The drain electrode DE may be connected to the active pattern ACT (e.g., the drain region) through an opening defined in the second to fourth insulating layers 103, 105, and 107. In one or more embodiments, the fourth conductive layer 108 may include at least one of materials such as, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) and may have a single-layer or multi-layer structure.

Although FIG. 8 shows one or more embodiments in which the second to fourth insulating layers 103, 105, and 107 each have a flat upper surface, embodiments are not limited thereto, and the second to fourth insulating layers 103, 105, and 107 may have an upper surface whose shape (e.g., unevenness) corresponds to that of a layer arranged under each of the second to fourth insulating layers 103, 105, and 107.

A fifth insulating layer 109 may be arranged over and/or on the fourth conductive layer 108. The fifth insulating layer 109 may cover and/or be arranged on the fourth conductive layer 108, for example, the source electrode SE and the drain electrode DE. The fifth insulating layer 109 may have a flat upper surface. The fifth insulating layer 109 may include an organic insulating material. In one or more embodiments, the fifth insulating layer 109 may include at least one of materials such as, for example, a general commercial polymer, such as benzocyclobutene, polyimide, hexamethyldisiloxane, poly(methyl methacrylate), or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer and may have a single-layer or multi-layer structure. In one or more embodiments, the fifth insulating layer 109 may be a first via layer.

A fifth conductive layer 110 may be arranged on the fifth insulating layer 109. The fifth conductive layer 110 may include a contact metal that connects the fourth conductive layer 108, for example, the drain electrode DE, to a first electrode 112 of the light-emitting diode LED. The fifth conductive layer 110 may include a gate electrode of another transistor, a signal line, a power line, etc. In one or more embodiments, the fifth conductive layer 110 may include at least one of materials such as, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) and may have a single-layer or multi-layer structure.

A sixth insulating layer 111 may be arranged over and/or on the fifth conductive layer 110. The sixth insulating layer 111 may cover and/or be arranged on the fifth conductive layer 110. The sixth insulating layer 111 may have a flat upper surface. The sixth insulating layer 111 may include an organic insulating material. In one or more embodiments, the sixth insulating layer 111 may include at least one of materials such as a polymer, such as, for example, benzocyclobutene, polyimide, hexamethyldisiloxane, poly(methyl methacrylate), or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer and may have a single-layer or multi-layer structure. In one or more embodiments, the sixth insulating layer 111 may be a second via layer.

The light-emitting diode LED may be arranged on the sixth insulating layer 111. The light-emitting diode LED may include the first electrode 112 and a second electrode 118 opposite to each other and an intermediate layer 114 between the first electrode 112 and the second electrode 118. In one or more embodiments, the first electrode 112 of the light-emitting diode LED may correspond to an anode, and the second electrode 118 thereof may correspond to a cathode.

The first electrode 112 of the light-emitting diode LED may be arranged on the sixth insulating layer 111. The first electrode 112 may be connected to the fifth conductive layer 110 through an opening defined in the sixth insulating layer 111. The first electrode 112 may be (e.g., electrically and/or physically) connected to the thin-film transistor TFT through the fifth conductive layer 110 and the drain electrode DE. The first electrode 112 may include conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). The first electrode 112 may include a reflection layer including, for example, silver (Ag), magnesium (Mg), aluminum (Al), platinum (Pt), palladium (Pd), gold (Au), nickel (Ni), neodymium (Nd), iridium (Ir), chromium (Cr), or a compound thereof. However, a structure and material of the first electrode 112 is not limited thereto and may be variously modified.

A pixel-defining layer 113 may be arranged on the sixth insulating layer 111. The pixel-defining layer 113 may cover and/or be arranged on edges of the first electrode 112. For example, the pixel-defining layer 113 may have an opening to expose a central portion of the first electrode 112. A size and shape of an emission area of the light-emitting diode LED may be determined by the opening of the pixel-defining layer 113. In one or more embodiments, the pixel-defining layer 113 may include an organic insulating material. In one or more embodiments, the pixel-defining layer 113 may include at least one of materials such as, for example, a general commercial polymer, such as benzocyclobutene, polyimide, hexamethyldisiloxane, poly(methyl methacrylate), or polystyrene, a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer and may have a single-layer or multi-layer structure.

The intermediate layer 114 may be arranged on the first electrode 112. The intermediate layer 114 may include a first common layer 115 and a second common layer 117 arranged on the pixel-defining layer 113 and an emission layer 116 arranged in the opening of the pixel-defining layer 113. The second common layer 117 may be arranged on the first common layer 115. In one or more embodiments, the first common layer 115 may be arranged on the pixel-defining layer 113, the emission layer 116 may be arranged on the first common layer 115 in the opening of the pixel-defining layer 113, and the second common layer 117 may be arranged over and/or on the first common layer 115 to cover and/or be arranged on the emission layer 116. In other words, the emission layer 116 may be arranged in the opening of the pixel-defining layer 113 and may be disposed between the first common layer 115 and the second common layer 117.

The emission layer 116 may include a low-molecular or high-molecular weight material that emits light of a certain color when current flows. The first common layer 115 may include an electron transport layer (ETL) and/or an electron injection layer (EIL). The second common layer 117 may include a hole transport layer (HTL) and/or a hole injection layer (HIL). In one or more embodiments, the first common layer 115 or the second common layer 117 may be omitted. In one or more embodiments, positions of the first common layer 115 and the second common layer 117 may be reversed.

The second electrode 118 may be arranged on the intermediate layer 114. For example, the second electrode 118 may be arranged on the second common layer 117. The second electrode 118 may entirely cover and/or be arranged on the intermediate layer 114. The second electrode 118 may include a conductive material. For example, the second electrode 118 may include a transparent layer (or a semitransparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 118 may further include a layer on a transparent layer (or a semitransparent layer) including the above-described material, the layer including oxide such as, for example, indium tin oxide (ITO), indium zinc oxide (IZO), zinc oxide (ZnO), or indium oxide (In₂O₃).

The thin-film encapsulation layer TFEL may be arranged on the second electrode 118 and may entirely cover and/or be arranged on the light-emitting diode LED. The thin film encapsulation layer TFEL may include at least one inorganic layer and at least one organic layer. In one or more embodiments, the thin-film encapsulation layer TFEL may include a first inorganic encapsulation layer 119, a second inorganic encapsulation layer 121, and an organic encapsulation layer 120 arranged between the first inorganic encapsulation layer 119 and the second inorganic encapsulation layer 121. In one or more embodiments, the first inorganic encapsulation layer 119 and the second inorganic encapsulation layer 121 may have an upper surface with a shape (e.g., unevenness) according to the shape of a layer arranged under the first inorganic encapsulation layer 119 and the second inorganic encapsulation layer 121. In one or more embodiments, the organic encapsulation layer 120 may have a flat upper surface.

The first inorganic encapsulation layer 119 and/or the second inorganic encapsulation layer 121 may include at least one of materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer or multi-layer structure. The organic encapsulation layer 120 may include a polymer-based material. Examples of the polymer-based material may include silicone-based resin, acryl-based resin, epoxy-based resin, polyimide, and polyethylene.

The touch sensing layer TSL may be arranged on the thin-film encapsulation layer TFEL. The touch sensing layer TSL may include a touch electrode layer for sensing an external input, for example, a touch event, and a touch insulating layer disposed between electrode layers. The touch sensing layer TSL may include a first touch insulating layer 122, a first touch electrode layer 123, a second touch insulating layer 124, a second touch electrode layer 125, and a third touch insulating layer 126.

The first touch insulating layer 122 may be arranged on the thin-film encapsulation layer TFEL, for example, the second inorganic encapsulation layer 121 of the thin-film encapsulation layer TFEL. The first touch electrode layer 123 may be arranged on the first touch insulating layer 122. The second touch insulating layer 124 may be arranged over and/or on the first touch electrode layer 123 and may cover and/or be arranged on the first touch electrode layer 123. The second touch electrode layer 125 may be arranged on the second touch insulating layer 124. The third touch insulating layer 126 may be arranged over and/or on the second touch electrode layer 125 and may cover and/or be arranged on the second touch electrode layer 125. The second touch electrode layer 125 may be connected to the first touch electrode layer 123 through an opening defined in the second touch insulating layer 124. In one or more embodiments, the second touch electrode layer 125 may include a sensing electrode, and the first touch electrode layer 123 may include a bridge electrode.

In one or more embodiments, the first touch insulating layer 122 may include an inorganic insulating material. In one or more embodiments, the first touch insulating layer 122 may include at least one of materials such as, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer or multi-layer structure.

In one or more embodiments, the second touch insulating layer 124 and the third touch insulating layer 126 may include an organic insulating material. In one or more embodiments, the second touch insulating layer 124 and/or the third touch insulating layer 126 may include an acryl-based organic insulating material. In one or more embodiments, the second touch insulating layer 124 and/or the third touch insulating layer 126 may have a flat upper surface.

The first touch electrode layer 123 and the second touch electrode layer 125 may not entirely overlap the emission area of the light-emitting diode LED in the z-axis direction. In one or more embodiments, the first touch electrode layer 123 and the second touch electrode layer 125 may not overlap the emission layer 116 of the light-emitting diode LED in the z-axis direction. For example, the first touch electrode layer 123 and the second touch electrode layer 125 may have an opening overlapping the emission area or the emission layer 116 of the light-emitting diode LED in the z-axis direction.

In FIG. 8, additional layers such as an optical functional layer, a physical functional layer, and a protection layer may be arranged on the touch sensing layer TSL.

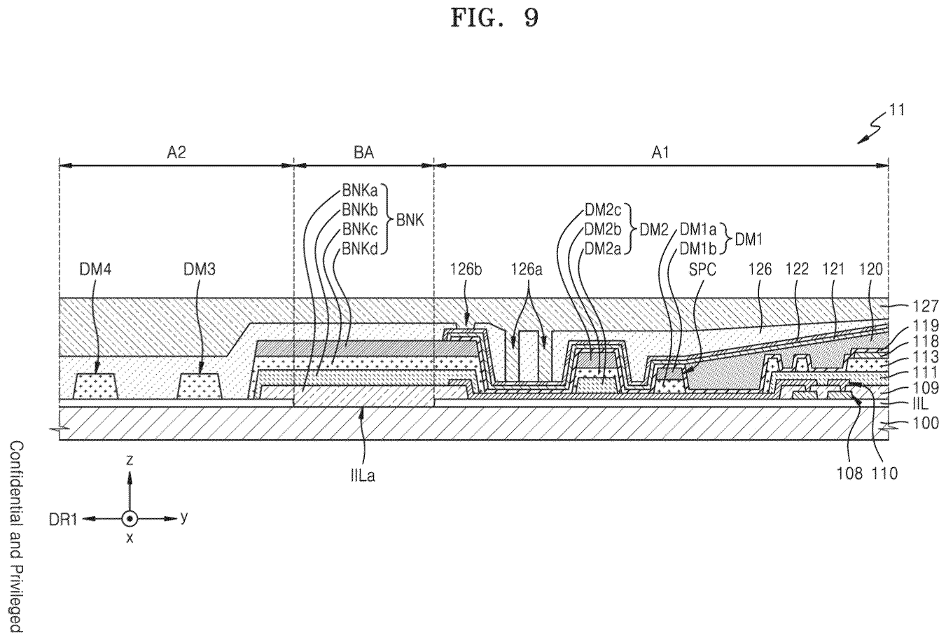

FIG. 9 is a cross-sectional view of the display panel 11 according to one or more embodiments. FIG. 9 may be a cross-sectional view of the display panel 11 in the first area A1, the second area A2, and the bending area BA.

Referring to FIG. 9, the inorganic insulating layer IIL, the fifth insulating layer 109, the sixth insulating layer 111, the pixel-defining layer 113, the first inorganic encapsulation layer 119, the organic encapsulation layer 120, the second inorganic encapsulation layer 121, the first touch insulating layer 122, and the third touch insulating layer 126 may extend into the first area A1. The second touch insulating layer 124 (refer to FIG. 8) may also partially extend into the first area A1. The fourth conductive layer 108, the fifth conductive layer 110, and the second electrode 118 may be (e.g., partially) arranged in the first area A1.

The first dam part DM1 and the second dam part DM2 may be arranged above and/or on the substrate 100 in the first area A1. The third dam part DM3 and the fourth dam part DM4 may be arranged above and/or on the substrate 100 in the second area A2. The bank part BNK may be arranged on the substrate 100 in the first area A1, the bending area BA, and the second area A2. The first dam part DM1, the second dam part DM2, the bank part BNK, the third dam part DM3, and the fourth dam part DM4 may include an organic insulating material.

The first dam part DM1 may be arranged above and/or on the inorganic insulating layer IIL. In one or more embodiments, the fifth conductive layer 110 may extend into the first area A1, and the first dam part DM1 may be arranged on the fifth conductive layer 110. In one or more embodiments, the first dam part DM1 may overlap the fifth conductive layer 110 in the z-axis direction. The first dam part DM1 may include a 1st-1 organic portion DM1a and a 1st-2 organic portion DM1b. The 1st-2 organic portion DM1b may be arranged on the 1st-1 organic portion DM1a.

In one or more embodiments, the 1st-1 organic portion DM1a may include the same material as that of the pixel-defining layer 113. In one or more embodiments, the 1st-1 organic portion DM1a may be formed simultaneously with the pixel-defining layer 113. In one or more embodiments, the 1st-1 organic portion DM1a may be understood as a portion of the pixel-defining layer 113.

In one or more embodiments, the display panel 11 may include a spacer layer SPC arranged on the pixel-defining layer 113 in the first area A1 and the bending area BA. The spacer layer SPC may be arranged on the pixel-defining layer 113 as a portion of each of the first dam part DM1, the second dam part DM2, and the bank part BNK. In FIG. 9, the spacer layer SPC may also be arranged in the second area A2 as a portion of the third dam part DM3 and the fourth dam part DM4. In one or more embodiments, the spacer layer SPC may include an organic insulating material. In one or more embodiments, the spacer layer SPC may include the same material as that of the pixel-defining layer 113, the fifth insulating layer 109 and/or the sixth insulating layer 111.

In one or more embodiments, the 1st-2 organic portion DM1b may include the same material as that of the spacer layer SPC. In one or more embodiments, the 1st-2 organic portion DM1b may be understood as a portion of the spacer layer SPC.

The second dam part DM2 may be arranged above the inorganic insulating layer IIL. The second dam part DM2 may be arranged in the first direction DR1 with respect to the first dam part DM1. In one or more embodiments, the second dam part DM2 may be arranged on the fifth conductive layer 110. In one or more embodiments, the second dam part DM2 may overlap the fifth conductive layer 110 in the z-axis direction. The second dam part DM2 may include a 2nd-1 organic portion DM2a, a 2nd-2 organic portion DM2b, and a 2nd-3 organic portion DM2c. The 2nd-2 organic portion DM2b may be arranged on the 2nd-1 organic portion DM2a, and in one or more embodiments, the 2nd-2 organic portion DM2b may entirely cover the 2nd-1 organic portion DM2a. The 2nd-3 organic portion DM2c may be arranged on the 2nd-2 organic portion DM2b.

In one or more embodiments, the 2nd-1 organic portion DM2a may include the same material as that of the sixth insulating layer 111. In one or more embodiments, the 2nd-1 organic portion DM2a may be formed simultaneously with the sixth insulating layer 111. In one or more embodiments, the 2nd-1 organic portion DM2a may be understood as a portion of the sixth insulating layer 111.

In one or more embodiments, the 2nd-2 organic portion DM2b may include the same material as that of the pixel-defining layer 113. In one or more embodiments, the 2nd-2 organic portion DM2b may be formed simultaneously with the pixel-defining layer 113. In one or more embodiments, the 2nd-2 organic portion DM2b may be a portion of the pixel-defining layer 113.

In one or more embodiments, the 2nd-3 organic portion DM2c may include the same material as that of the spacer layer SPC. In one or more embodiments, the 2nd-3 organic portion DM2c may be understood as a portion of the spacer layer SPC.

The bank part BNK may be arranged on the substrate 100. The bank part BNK may be arranged in the first direction DR1 with respect to the second dam part DM2. In one or more embodiments, a portion of the bank part BNK may be arranged in the first area A1. In one or more embodiments, another portion of the bank part BNK may be arranged in the second area A2. In one or more embodiments, one end, for example, an end facing in the y-axis direction, of the bank part BNK may be arranged in the first area A1. In one or more embodiments, the other end, for example, an end facing in the first direction DR1, of the bank part BNK may be arranged in the second area A2. In one or more embodiments, a portion of the bank part BNK that is arranged in the first area A1 may overlap the fifth conductive layer 110 in the z-axis direction. The bank part BNK may include a 3rd-1 organic portion BNKa, a 3rd-2 organic portion BNKb, a 3rd-3 organic portion BNKc, and a 3rd-4 organic portion BNKd. The 3rd-2 organic portion BNKb may be arranged over and/or on the 3rd-1 organic portion BNKa and may entirely cover and/or be arranged on the 3rd-1 organic portion BNKa. The 3rd-3 organic portion BNKc may be arranged over and/or on the 3rd-2 organic portion BNKb and may entirely cover and/or be arranged on the 3rd-2 organic portion BNKb. The 3rd-4 organic portion BNKd may be arranged on the 3rd-3 organic portion BNKc.

In one or more embodiments, the 3rd-1 organic portion BNKa may include the same material as that of the fifth insulating layer 109. In one or more embodiments, the 3rd-1 organic portion BNKa may be formed simultaneously with the fifth insulating layer 109. In one or more embodiments, the 3rd-1 organic portion BNKa may be a portion of the fifth insulating layer 109.

In one or more embodiments, the 3rd-2 organic portion BNKb may include the same material as that of the sixth insulating layer 111. In one or more embodiments, the 3rd-2 organic portion BNKb may be formed simultaneously with the sixth insulating layer 111. In one or more embodiments, the 3rd-2 organic portion BNKb may be a portion of the sixth insulating layer 111. In one or more embodiments, a portion of the fifth conductive layer 110 that overlaps the bank part BNK may be arranged between the 3rd-1 organic portion BNKa and the 3rd-2 organic portion BNKb.

In one or more embodiments, the 3rd-3 organic portion BNKc may include the same material as a material of the pixel-defining layer 113. In one or more embodiments, the 3rd-3 organic portion BNKc may be formed simultaneously with the pixel-defining layer 113. In one or more embodiments, the 3rd-3 organic portion BNKc may be a portion of the pixel-defining layer 113.

In one or more embodiments, the 3rd-4 organic portion BNKd may include the same material as that of the spacer layer SPC. In one or more embodiments, the 3rd-4 organic portion BNKd may be a portion of the spacer layer SPC.

In one or more embodiments, some layers of the display panel 11 may be removed in the bending area BA to facilitate the above-described bending of the display panel 11. In one or more embodiments, the inorganic insulating layer IIL may be removed in the bending area BA. For example, an opening IILa corresponding to the bending area BA may be defined in the inorganic insulating layer IIL. In one or more embodiments, the bank part BNK, for example, the 3rd-1 organic portion BNKa of the bank part BNK, may be in direct contact with the substrate 100 through the opening IILa of the inorganic insulating layer IIL in the bending area BA.

The third dam part DM3 may be arranged on the inorganic insulating layer IIL. The third dam part DM3 may be arranged in the first direction DR1 with respect to the bank part BNK. In one or more embodiments, the third dam part DM3 may include the same material as the material of the pixel-defining layer 113. In one or more embodiments, the third dam part DM3 may be formed simultaneously with the pixel-defining layer 113. In one or more embodiments, the third dam part DM3 may be understood as a portion of the pixel-defining layer 113. Although FIG. 9 shows the third dam part DM3 as a single layer including the same material as the material of the pixel-defining layer 113, embodiments are not limited thereto. The third dam part DM3 may include, for example, at least one layer including the same material as a material of at least one of the fifth insulating layer 109, the sixth insulating layer 111, the pixel-defining layer 113, and the spacer layer SPC and may have a multi-layer structure. In one or more embodiments, the third dam part DM3 may extend toward the bending area BA and may be integrally formed with the bank part BNK, for example, the 3rd-3 organic portion BNKc of the bank part BNK.

The fourth dam part DM4 may be arranged on the inorganic insulating layer IIL. The fourth dam part DM4 may be arranged in the first direction DR1 with respect to the third dam part DM3. In one or more embodiments, the third dam part DM3 and the fourth dam part DM4 may be apart from each other. In one or more embodiments, the fourth dam part DM4 may include the same material as the material of the pixel-defining layer 113. In one or more embodiments, the fourth dam part DM4 may be formed simultaneously with the pixel-defining layer 113. In one or more embodiments, the fourth dam part DM4 may be a portion of the pixel-defining layer 113. Although FIG. 9 shows the fourth dam part DM4 as a single layer including the same material as that of the pixel-defining layer 113, embodiments are not limited thereto. The fourth dam part DM4 may include, for example, at least one layer including the same material as that of at least one of the fifth insulating layer 109, the sixth insulating layer 111, the pixel-defining layer 113, and the spacer layer SPC and may have a multi-layer structure.

The first inorganic encapsulation layer 119 may extend to the first area A1 and may at least partially (e.g., entirely) cover and/or be arranged on the first dam part DM1 and the second dam part DM2. The first inorganic encapsulation layer 119 may also partially cover and/or be arranged on a portion of the bank part BNK that is arranged in the first area A1. The second inorganic encapsulation layer 121 may be arranged over and/or on the first inorganic encapsulation layer 119 and may cover and/or be arranged on the first inorganic encapsulation layer 119. The first touch insulating layer 122 may be arranged over and/or on the second inorganic encapsulation layer 121 and may cover and/or be arranged on the second inorganic encapsulation layer 121. The first inorganic encapsulation layer 119, the second inorganic encapsulation layer 121, and the first touch insulating layer 122 may be arranged in the first area A1, and each edge thereof may be arranged on the bank part BNK in the first area A1.

The organic encapsulation layer 120 may be arranged between the first inorganic encapsulation layer 119 and the second inorganic encapsulation layer 121. When the organic encapsulation layer 120 is formed, the organic encapsulation layer 120 may have fluidity and may flow from the first area A1 to the bending area BA, for example, in the first direction DR1. A height (or thickness) of the first dam part DM1 and the second dam part DM2 in the z-axis direction may be configured to prevent such flow of the organic encapsulation layer 120. In one or more embodiments, flow of the organic encapsulation layer 120 may be stopped by the first dam part DM1. In one or more embodiments, flow of the organic encapsulation layer 120 may be stopped by the second dam part DM2, and in this case, the organic encapsulation layer 120 may be partially arranged between the first dam part DM1 and the second dam part DM2. In one or more embodiments, flow of the organic encapsulation layer 120 may be stopped by the bank part BNK, and in this case, the organic encapsulation layer 120 may be partially arranged between the first dam part DM1 and the second dam part DM2 and between the second dam part DM2 and the bank part BNK. One or more embodiments in which flow of the organic encapsulation layer 120 is stopped by the first dam part DM1 is mainly described below.

In an area where the organic encapsulation layer 120 is not arranged, the first inorganic encapsulation layer 119 and the second inorganic encapsulation layer 121 may be in direct contact with each other. In one or more embodiments, the first inorganic encapsulation layer 119 and the second inorganic encapsulation layer 121 may be in direct contact with each other between the first dam part DM1 and the second dam part DM2. In one or more embodiments, the first inorganic encapsulation layer 119 and the second inorganic encapsulation layer 121 may be in direct contact with each other between the second dam part DM2 and the bank part BNK.

The third touch insulating layer 126 may cover and/or be arranged on the first touch insulating layer 122, the bank part BNK, the third dam part DM3, and the fourth dam part DM4 and may extend across the first area A1, the bending area BA, and the second area A2. In one or more embodiments, a first groove 126a and a second groove 126b may be defined in the third touch insulating layer 126. For example, the third touch insulating layer 126 may be patterned to form the first groove 126a and the second groove 126b.

In one or more embodiments, the first groove 126a may be arranged between the second dam part DM2 and the bank part BNK. In one or more embodiments, the first groove 126a may include a plurality of first grooves 126a. Although FIG. 9 shows one or more embodiments in which two first grooves 126a are arranged between the second dam part DM2 and the bank part BNK, embodiments are not limited to a certain number of first grooves 126a. In one or more embodiments, the first groove 126a may be a through hole penetrating through the third touch insulating layer 126.

In one or more embodiments, the second groove 126b may overlap the bank part BNK in the z-axis direction. In one or more embodiments, the second groove 126b may overlap portions of the first touch insulating layer 122, the second inorganic encapsulation layer 121, and the first inorganic encapsulation layer 119 that are arranged on the bank part BNK. In one or more embodiments, a portion of the first touch insulating layer 122 may be exposed through the second groove 126b.

A planarization layer 127 may be arranged on the third touch insulating layer 126. The planarization layer 127 may entirely cover and/or be arranged on the first dam part DM1, the second dam part DM2, the third dam part DM3, the fourth dam part DM4, and the bank part BNK together with the third touch insulating layer 126. The planarization layer 127 may have a flat upper surface and may include an organic insulating material.

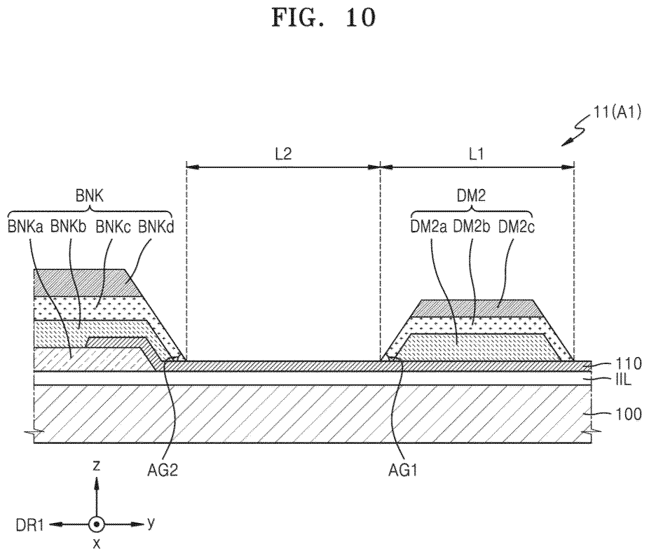

FIG. 10 is an enlarged cross-sectional view of the display panel 11 according to one or more embodiments. FIG. 10 may be an enlarged cross-sectional view of the first area A1 of the display panel 11. Although some layers are omitted in FIG. 10, this is merely for convenience of illustration and description and is not for purposes of limitation.

Referring to FIG. 10, a width (or length) of the second dam part DM2 measured in the y-axis direction from the first area A1 to the second area A2 (refer to FIG. 9), for example, the first direction DR1, may be defined as a first length L1. In one or more embodiments, the first length L1 may correspond to a distance between an edge of the second dam part DM2 that faces in the y-axis direction and an edge of the second dam part DM2 that faces in the first direction DR1. In one or more embodiments, the first length L1 may correspond to a distance between edges of the 2nd-2 organic portion DM2b that are in contact with the fifth conductive layer 110, for example, an edge facing in the y-axis direction and an edge facing in the first direction DR1.

In one or more embodiments, the first length L1 may be about 51 micrometers (μm) or less. In one or more embodiments, the first length L1 may be about 10 micrometers (μm) to about 50 micrometers (μm). In one or more embodiments, the first length L1 may be about 10 micrometers (μm) to about 36 micrometers (μm). In one or more embodiments, the first length L1 may be about 10 micrometers (μm) to about 21 micrometers (μm). In one or more embodiments, as the first length L1 decreases, that is, as a width of the second dam part DM2 decreases, stress applied to the display panel 11 in the first area A1 may decrease. Such a decrease in stress may reduce the occurrence of cracks in the display panel 11 in the first area A1.

A distance between the second dam part DM2 and the bank part BNK measured in the y-axis direction from the first area A1 to the second area A2 (refer to FIG. 9), for example, the first direction DR1, may be defined as a second length L2. In one or more embodiments, the second length L2 may correspond to a distance between an edge of the second dam part DM2 that faces in the first direction DR1 and an edge of the bank part BNK that faces in the y-axis direction. In one or more embodiments, the second length L2 may correspond to a distance between an edge of the 2nd-2 organic portion DM2b that is in contact with the fifth conductive layer 110 and faces the bank part BNK and an edge of the 3rd-3 organic portion BNKc that is in contact with the fifth conductive layer 110 and faces the second dam part DM2.

In one or more embodiments, the second length L2 may be about 30 micrometers (μm) or greater. In one or more embodiments, the second length L2 may be about 50 micrometers (μm) or greater. In one or more embodiments, the second length L2 may be about 65 micrometers (μm) or greater. In one or more embodiments, the second length L2 may be about 80 micrometers (μm) or greater. In one or more embodiments, as the second length L2 increases, that is, as a distance between the second dam part DM2 and the bank part BNK increases, stress applied to the display panel 11 in the first area A1 may decrease. Such a decrease in stress may reduce the occurrence of cracks in the display panel 11 in the first area A1.

In one or more embodiments, the second dam part DM2 may have a tapered shape. For example, a side surface of the second dam part DM2 may have a certain angle with respect to a lower surface of the second dam part DM2. In one or more embodiments, an angle between the side surface of the second dam part DM2 and the lower surface of the second dam part DM2 may be defined as a first angle AG1. In one or more embodiments, an angle between a side surface of the 2nd-2 organic portion DM2b and a lower surface of the 2nd-2 organic portion DM2b or an angle between a side surface of the 2nd-2 organic portion DM2b and a lower surface of the 2nd-1 organic portion DM2a may be defined as the first angle AG1. In one or more embodiments, an angle between the side surface of the second dam part DM2 (e.g., the side surface of the 2nd-2 organic portion DM2b) and an upper surface of the fifth conductive layer 110 may be defined as the first angle AG1. In one or more embodiments, the first angle AG1 may be about 60 degrees or less. In one or more embodiments, the first angle AG1 may be about 30 degrees to about 50 degrees.

In one or more embodiments, the bank part BNK may have a tapered shape. For example, a side surface of the bank part BNK may have a certain angle to a lower surface of the bank part BNK. In one or more embodiments, an angle between the side surface of the bank part BNK and the lower surface of the bank part BNK may be defined as a second angle AG2. In one or more embodiments, an angle between a side surface of the 3rd-3 organic portion BNKc and a lower surface of the 3rd-3 organic portion BNKc or an angle between a side surface of the 3rd-3 organic portion BNKc and a lower surface of the 3rd-2 organic portion BNKb may be defined as a second angle AG2. In one or more embodiments, an angle between the side surface of the bank part BNK (e.g., the side surface of the 3rd-3 organic portion BNKc) and an upper surface of the fifth conductive layer 110 may be defined as the second angle AG2. In one or more embodiments, the second angle AG2 may be about 60 degrees or less. In one or more embodiments, the second angle AG2 may be about 30 degrees to about 50 degrees.

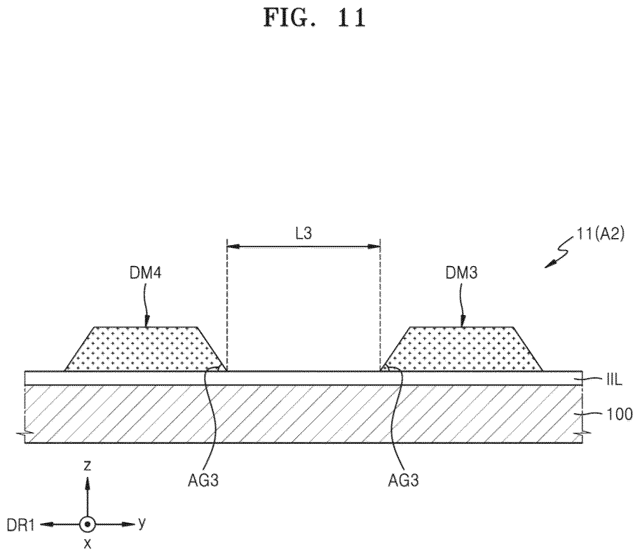

FIG. 11 is an enlarged cross-sectional view of the display panel 11 according to one or more embodiments. FIG. 11 may be an enlarged cross-sectional view of the second area A2 of the display panel 11. Although some layers are omitted in FIG. 11, this is merely for convenience of illustration and description and is not for purposes of limitation.

Referring to FIG. 11, a distance between the third dam part DM3 and the fourth dam part DM4 measured in the y-axis direction from the first area A1 (refer to FIG. 9) to the second area A2, for example, the first direction DR1, may be defined as a third length L3. In one or more embodiments, the third length L3 may correspond to a distance between an edge of the third dam part DM3 that faces in the first direction DR1 and an edge of the fourth dam part DM4 that faces in the y-axis direction. In one or more embodiments, the third length L3 may correspond to a distance between an edge of the third dam part DM3 that is in contact with the inorganic insulating layer IIL and faces the fourth dam part DM4 and an edge of the fourth dam part DM4 that is in contact with the inorganic insulating layer IIL and faces the third dam part DM3.

In one or more embodiments, the third length L3 may be about 28 micrometers (μm) or greater. In one or more embodiments, the third length L3 may be about 30 micrometers (μm) to about 120 micrometers (μm). In one or more embodiments, the third length L3 may be about 50 micrometers (μm) to about 120 micrometers (μm). In one or more embodiments, the third length L3 may be about 70 micrometers (μm) to about 120 micrometers (μm). In one or more embodiments, the third length L3 may be about 90 micrometers (μm) to about 120 micrometers (μm). In one or more embodiments, as the third length L3 increases, that is, as a distance between the third dam part DM3 and the fourth dam part DM4 increases, stress applied to the display panel 11 in the second area A2 may decrease. Such a decrease in stress may reduce the occurrence of cracks in the display panel 11 in the second area A2.

In one or more embodiments, the third dam part DM3 and the fourth dam part DM4 may have a tapered shape. In one or more embodiments, a side surface of the third dam part DM3 may have a certain angle with respect to a lower surface of the third dam part DM3. In one or more embodiments, an angle between the side surface of the third dam part DM3 and the lower surface of the third dam part DM3 may be defined as a third angle AG3. In one or more embodiments, an angle between the side surface of the third dam part DM3 and an upper surface of the inorganic insulating layer IIL may be defined as the third angle AG3. In one or more embodiments, an angle between a side surface of the fourth dam part DM4 and a lower surface of the fourth dam part DM4 may be defined as the third angle AG3. In one or more embodiments, an angle between the side surface of the fourth dam part DM4 and an upper surface of the inorganic insulating layer IIL may be defined as the third angle AG3. FIG. 11 shows one or more embodiments in which the third dam part DM3 and the fourth dam part DM4 have the same taper angle (e.g., the third angle AG3). However, in another embodiment, the third dam part DM3 and the fourth dam part DM4 may have different taper angles. For example, the third dam part DM3 may have the third angle AG3 as a taper angle, and the fourth dam part DM4 may have a fourth angle as a taper angle.

In one or more embodiments, the third angle AG3 may be about 60 degrees or less. In one or more embodiments, the third angle AG3 may be about 30 degrees to about 50 degrees.

The display panel 11 according to embodiments does not necessarily include all of the features regarding the first length L1, the second length L2, and the third length L3 described above with reference to FIGS. 10 and 11. In one or more embodiments, the display panel 11 may include only the features regarding the first length L1, may include only the features regarding the second length L2, or may include only the features regarding the third length L3. In one or more embodiments, the display panel 11 may include the features regarding the first length L1 and the features regarding the second length L2. In one or more embodiments, the display panel 11 may include the features regarding the second length L2 and the features regarding the third length L3. In one or more embodiments, the display panel 11 may include the features regarding the first length L1 and the features regarding the third length L3. In one or more embodiments, the display panel 11 may include all of the features regarding the first length L1, the features regarding the second length L2, and the features regarding the third length L3. In other words, the display panel 11 may include at least one of the features regarding each of the first length L1, the second length L2, and the third length L3 described above.

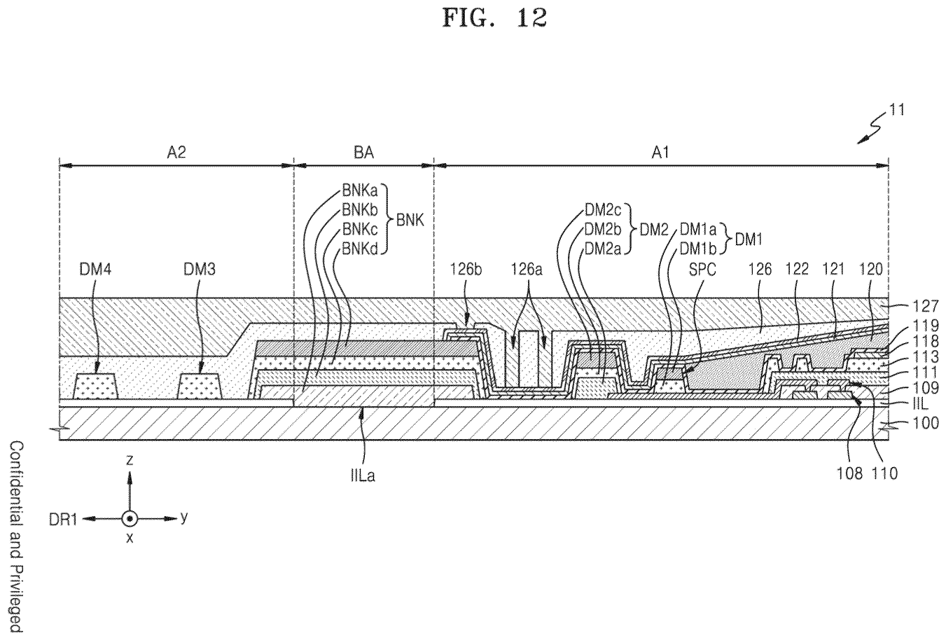

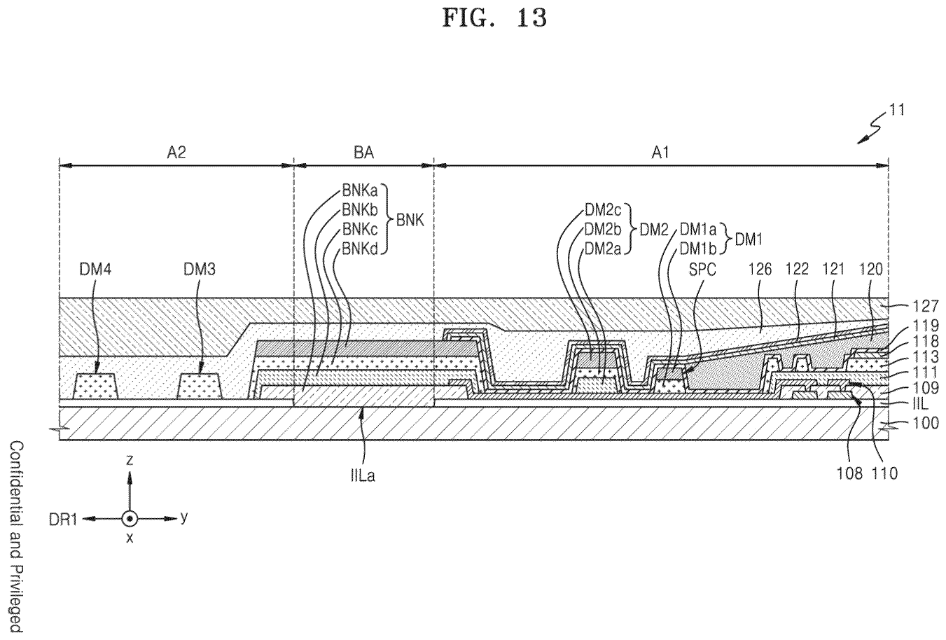

FIG. 12 is a cross-sectional view of the display panel 11 according to one or more embodiments. FIG. 13 is a cross-sectional view of the display panel 11 according to one or more embodiments. FIGS. 12 and 13 may be cross-sectional views of the display panel 11 in the first area A1, the second area A2, and the bending area BA. A description of features that are substantially the same as those of the embodiment described with reference to FIG. 9 is omitted, and differences are mainly described below.

Referring to FIG. 12, the fifth conductive layer 110 may not overlap the bank part BNK in the z-axis direction. In one or more embodiments, the fifth conductive layer 110 may partially extend in the first area A1. In one or more embodiments, the fifth conductive layer 110 may overlap the first dam part DM1. In one or more embodiments, the fifth conductive layer 110 may overlap the second dam part DM2 in the z-axis direction. In one or more embodiments, a portion of the second dam part DM2 may overlap the fifth conductive layer 110 in the z-axis direction. Referring to FIG. 9 again, the first inorganic encapsulation layer 119 may be in direct contact with an upper surface of the fifth conductive layer 110 between the second dam part DM2 and the bank part BNK. On the other hand, referring to FIG. 12, the first inorganic encapsulation layer 119 may be in direct contact with the inorganic insulating layer IIL between the second dam part DM2 and the bank part BNK.

The display panel 11 of FIG. 9 and the display panel 11 of FIG. 12 may be display panels 11 according to different embodiments. Alternatively, FIGS. 9 and 12 may be cross-sectional views taken at different areas of the same display panel 11. For example, FIGS. 9 and 12 may be cross-sectional views of different areas of one embodiment. For example, the fifth conductive layer 110 may have a different extension length or range depending on an area of the display panel 11 where the fifth conductive layer 110 is arranged. For example, the fifth conductive layer 110 may extend to overlap the bank part BNK in the z-axis direction as shown in FIG. 9 in an area, and may extend not to overlap the bank part BNK as shown in FIG. 12 in another area.

Referring to FIG. 13, the first groove 126a and the second groove 126b (refer to FIG. 9) of the third touch insulating layer 126 may be omitted. Accordingly, the third touch insulating layer 126 may cover and/or be arranged on the first touch insulating layer 122, the bank part BNK, the third dam part DM3, and the fourth dam part DM4 and may be integrally formed as a whole across the first area A1, the bending area BA, and the second area A2.

According to one or more embodiments, a display panel including a configuration whereby cracks that occur in a bending area of a display panel may be reduced is provided. In addition, an electronic device including the display panel may be provided. Thus, the display panel and the electronic device may have improved quality.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a substrate comprising:
a display area;
a bending area at one side of the display area;
a first area between the display area and the bending area; and
a second area, wherein the bending area is between the first area and the second area;
a light-emitting diode in the display area;
a first dam part and a second dam part in the first area;
a bank part extending across the bending area; and
a third dam part and a fourth dam part in the second area,
wherein, when viewed in a direction from the first area to the second area, at least one of the following three conditions is satisfied:
a width of the second dam part is less than or equal to 51 micrometers;
a distance between the second dam part and the bank part is greater than or equal to 30 micrometers; and
a distance between the third dam part and the fourth dam part is greater than or equal to 28 micrometers in a direction from the first area to the second area.

2. The display panel of claim 1, wherein the width of the second dam part is greater than or equal to 10 micrometers and less than or equal to 50 micrometers.

3. The display panel of claim 1, wherein the distance between the second dam part and the bank part is greater than or equal to 50 micrometers.

4. The display panel of claim 1, wherein the distance between the third dam part and the fourth dam part is greater than or equal to 30 micrometers and less than or equal to 120 micrometers.

5. The display panel of claim 1, wherein an angle between a side surface of the second dam part and a lower surface of the second dam part is less than or equal to 60 degrees.

6. The display panel of claim 1, wherein an angle between a side surface of the bank part and a lower surface of the bank part is less than or equal to 60 degrees.

7. The display panel of claim 1, wherein an angle between a side surface of the third dam part and a lower surface of the third dam part or an angle between a side surface of the fourth dam part and a lower surface of the fourth dam part is less than or equal to 60 degrees.

8. The display panel of claim 1, further comprising:
a first inorganic encapsulation layer at least partially on the first dam part, the second dam part, and the bank part; and
a second inorganic encapsulation layer on the first inorganic encapsulation layer,
wherein the first inorganic encapsulation layer and the second inorganic encapsulation layer are in direct contact with each other between the second dam part and the bank part.

9. The display panel of claim 8, further comprising an inorganic insulating layer below the first dam part, the second dam part, the bank part, the third dam part, and the fourth dam part,
wherein the first inorganic encapsulation layer and the inorganic insulating layer are in direct contact with each other between the second dam part and the bank part.

10. The display panel of claim 9, wherein the inorganic insulating layer comprises an opening corresponding to the bending area.

11. The display panel of claim 1, further comprising a conductive layer below the first dam part,
wherein the conductive layer overlaps the first dam part and the second dam part.

12. The display panel of claim 11, wherein the conductive layer overlaps the bank part.

13. The display panel of claim 1, further comprising a touch sensing layer on the light-emitting diode, the touch sensing layer comprising a touch insulating layer and a touch conductive layer,
wherein a portion of the touch insulating layer extends to the first area and comprises a groove between the second dam part and the bank part.

14. The display panel of claim 1, further comprising a planarization layer on the first dam part, the second dam part, the bank part, the third dam part, and the fourth dam part.

15. The display panel of claim 1, wherein the bank part and the substrate are in direct contact with each other in the bending area.

16. The display panel of claim 15, wherein a portion of the substrate that corresponds to the bending area is bent, and
wherein a second portion of the substrate that corresponds to the second area is below a bottom surface of a first portion of the substrate that corresponds to the first area.

17. The display panel of claim 1, wherein the first dam part, the second dam part, the bank part, the third dam part, and the fourth dam part comprise an organic insulating material.

18. The display panel of claim 1, wherein the first area is in a first direction with respect to the display area,
wherein the bending area is in the first direction with respect to the first area,
wherein the second area is in the first direction with respect to the bending area,
wherein the second dam part is in the first direction with respect to the first dam part,
wherein the bank part is in the first direction with respect to the second dam part,
wherein the third dam part is in the first direction with respect to the bank part, and
wherein the fourth dam part is in the first direction with respect to the third dam part.

19. A display panel comprising:
a substrate comprising:
a display area;
a bending area in a first direction with respect to the display area;
a first area between the display area and the bending area; and
a second area in the first direction with respect to the bending area opposite to the first area;
a light-emitting diode in the display area;
a first dam part in the first area;
a second dam part in the first direction with respect to the first dam part, the second dam part having a first length in the first direction;
a bank part spaced apart from the second dam part by a second length in the first direction and extending across the bending area; and
a third dam part and a fourth dam part in the second area and spaced apart from each other by a third length in the first direction,
wherein at least one of the following three conditions is satisfied:
the first length is less than or equal to 51 micrometers; the second length is greater than or equal to 30 micrometers; and the third length is greater than or equal to 28 micrometers.

20. An electronic device comprising:
a display panel; and
a processor configured to drive the display panel,
wherein the display panel comprises:
a substrate comprising:
a display area;
a bending area at one side of the display area;
a first area between the display area and the bending area; and
a second area, wherein the bending area is between the first area and the second area;
a light-emitting diode in the display area;
a first dam part and a second dam part in the first area;
a bank part extending across the bending area; and
a third dam part and a fourth dam part in the second area,
wherein, when viewed in a direction from the first area to the second area, at least one of the following three conditions is satisfied:
a width of the second dam part is less than or equal to 51 micrometers;
a distance between the second dam part and the bank part is greater than or equal to 30 micrometers; and
a distance between the third dam part and the fourth dam part is greater than or equal to 28 micrometers in a direction from the first area to the second area.
